(19) United States
(12) Patent Application Publication
(10) Pub. No.: US 2012/0104233 A1
(43) Pub. Date: May 3, 2012

(54) SOLID-STATE IMAGING DEVICE AND METHOD OF DRIVING THE SAME

(75) Inventors: Hideaki MORI, Hyogo (JP); Yutaka ABE, Osaka (JP); Kunihiko HARA, Osaka (JP)

(73) Assignee: PANASONIC CORPORATION, Osaka (JP)

(21) Appl. No.: 13/337,563

(22) Filed: Dec. 27, 2011

Related U.S. Application Data
(63) Continuation of application No. PCT/JP2010/004397, filed on Jul. 6, 2010.

(30) Foreign Application Priority Data
Jul. 6, 2009 (JP) 2009-160091

(51) Int. Cl. H01L 27/146

(52) U.S. Cl. 250/208.1

(57) ABSTRACT

A solid-state imaging device counts down clock pulses until a comparator indicates a predetermined comparison result using a counter while comparing, in the comparator, a reset component outputted from one of pixel circuits which is yet to receive light with a reference signal, and holds in a latch a value indicated by the counter as a result of the count down. The solid-state imaging device counts up, after presetting the value held in the latch to the counter, the clock pulses until the comparator indicates a predetermined comparison result using the counter while comparing, in the comparator, a signal component outputted from one of the pixel circuits which has received light with the reference signal, and outputs a value indicated by the counter as a result of the count up as a digital signal that indicates an amount of light received by the one of the pixel circuits.

### CROSS REFERENCE TO RELATED APPLICATIONS

This is a continuation application of PCT Patent Application No. PCT/JP2010/004397 filed on Jul. 6, 2010, designating the United States of America, which is based on and claims priority of Japanese Patent Application No. 2009-160091 filed on Jul. 6, 2009. The entire disclosures of the above-identified applications, including the specifications, drawings and claims are incorporated herein by reference in their entirety.

### BACKGROUND OF THE INVENTION

(1) Field of the Invention

The present invention relates to solid-state imaging devices, and particularly to a MOS solid-state imaging device such as a CMOS image sensor and a driving method of the MOS solid-state imaging device.

(2) Description of the Related Art

In recent years, various configurations and signal readout methods have been presented regarding a CMOS image sensor, which is a type of a solid-state imaging device. Generally, column-parallel output CMOS image sensors are widely used which select pixels of a row within a pixel array (imaging region) and read out in parallel, through a vertical signal line (also called a “column signal line”), pixel signals each of which is generated by one of the selected pixels. Furthermore, column A/D image sensors have also been presented in which an AD conversion circuit is provided for each vertical signal line, and the pixel signals are converted from analog format to digital format in CMOS image sensors.

FIG. 9 is a schematic diagram of a solid-state imaging device 900 described in Japanese Unexamined Patent Application Publication No. 2005-323331 (Patent Reference 1).

The solid-state imaging device 900 according to Patent Reference 1 includes: a pixel array 110 in which a plurality of pixel circuits 111 are arranged in rows and columns; column AD (Analog Digital) conversion circuits 120 each of which is provided for a corresponding one of the columns of the pixel array 110; a reference signal generating unit 150 which generates, using a DAC (Digital Analog Converter), a reference signal RAMP which varies over time at a predetermined change rate; a timing control unit 140 which controls various timings; and an output circuit 130.

The timing control unit 140 generates various internal clocks based on a master clock CLK₀, and also generates an operation timing control signal for each of blocks.

The signal outputted from each of the pixel circuits 111 is supplied to the corresponding one of the column AD conversion circuits 120 through a vertical signal line 119 (H₀, H₁ . . . , Hₘ).

Each of the column AD conversion circuits 120 includes: a comparator 121, a counter 122, and a memory 123. The comparator 121 compares the reference signal RAMP obtained from the reference signal generating unit 150 with a pixel signal obtained from the pixel circuit 111 through the corresponding one of the vertical signal lines 119. The counter 122 counts clock pulses inputted. The memory 123 holds, according to a control signal CN₃ from the timing control unit 140, a count value obtained as a result of counting performed by the counter 122 from when the reference signal generating unit 150 causes the reference signal to start to vary to when the comparator 121 indicates that the pixel signal matches the reference signal. The pixel signal held in the memory 123 is outputted as video data D₁ to the outside via an output signal line 125 and the output circuit 130.

Here, the comparator 121 includes an input capacitance for pixel noise cancelling, and performs a Correlated Double Sampling (CDS) by analog processing (hereinafter referred to as an “analog CDS”) according to a reset signal RST at the time when the pixel signal is read out. The reset signal RST is also used for resetting the counter 122. The counter 122 performs a counting operation by switching between an up-count mode and a down-count mode according to a control signal CN₂ from the timing control unit 140.

Next, an operation performed by the solid-state imaging device 900 according to Patent Reference 1 is described. Especially, an AD conversion of the pixel signal performed by the column AD conversion circuit 120 is described.

FIG. 10 is a timing diagram showing the operation performed by the solid-state imaging device 900 according to Patent Reference 1.

The timing control unit 140 resets a count value of the counter 122 to an initial value 0 with the reset signal RST and sets the counter 122 to the down-count mode with the control signal CN₂ (time t₁). Furthermore, the timing control unit 140 causes each of the pixel circuits 111 in rows Vₓ (x=0, 1, 2 . . . , n) to read out a pixel signal having a reset component ΔV. The pixel signal that is read out appears in the corresponding one of the vertical signal lines 119 (H₀, H₁ . . . , Hₘ).

The timing control unit 140 resets the comparator 121, and provides control signal CN₁ to the reference signal generating unit 150 when the pixel signal in the vertical signal line 119 becomes stable (time t₂). In response, the reference signal generating unit 150 starts temporal variation of the reference signal RAMP. Simultaneously, the timing control unit 140 starts to provide a clock CK₀ to the counter 122 (time t₂). In response, the counter 122 starts to count down from the initial value 0.

The reference signal RAMP varies over time, and matches the reset component ΔV at a certain point of time (time t₃). Here, an output signal of the comparator 121 is inverted, and the counter 122 stops counting down accordingly. The count value at this time corresponds to the reset component ΔV.

At the end of a down-count period (time t₄), the timing control unit 140 stops providing the control signal CN₁ to the reference signal generating unit 150, and simultaneously stops providing the clock CK₀ to the counter 122.

Subsequently, the timing control unit 140 sets the counter 122 to the up-count mode, and causes each of the pixel circuits 111 in the row Vₓ to read out a pixel signal having a signal component V_{sig}. The timing control unit 140 performs a counting operation on the pixel signal that is read out. Apart from setting the counter 122 to the up-count mode, the counting operation is performed in the same manner as for the readout of the reset component ΔV.

Thus, the counter 122 is set to the down-count mode when the reset component ΔV is read out and to the up-count mode when the signal component V_{sig} is read out. With this, a subtraction is automatically performed within the counter 122, making it possible to obtain a count value corresponding to the signal component V_{sig}.

Furthermore, by switching between the down-count mode and the up-count mode, it is possible to perform a CDS by digital processing (hereinafter referred to as a “digital CDS”) on variations such as clock skew variation and counter delay variation in each column, which result in a conversion error in the column AD conversion circuit 120.

As described above, the column AD conversion circuit 120 performs the analog CDS and the digital CDS at the time when each of the pixels of all the rows V_{X} is read out.

FIG. 11 shows operations in one frame performed by the solid-state imaging device 900 according to Patent Reference 1. When a first row to an n-th row are read out in a k-th frame, the down-count period that is for reading the reset component of the pixel and an up-count period that is for reading the signal component of the pixel are necessary to read out each of the pixels in each row.

Recent years have seen a strong demand for higher pixel count and higher precision. The high pixel count leads to an increase in the number of rows, which largely affects a frame rate. The high precision leads to an increase in the number of bits for AD conversion and thus increases an AD conversion period (increase in one horizontal scanning period), which largely affects the frame rate.

Furthermore, a counting operation is performed with high speed clock during the down-count period and the up-count period. This leads to a problem that each of the counters consumes a larger amount of power.

In particular, because the column AD conversion circuit 120 is provided for each of the columns of the pixel array 110 and the number of the columns is large, the power consumed by each of the column AD conversion circuits 120 amounts to a large portion of the overall power consumption of the solid-state imaging device 900. In addition, when a speed of a counter clock is reduced to suppress power consumption, an AD conversion period is increased. This causes a problem of decreased frame rate.

In view of the above problems, the present invention has an object to provide a solid-state imaging device and a driving method of the solid-state imaging device which can achieve a high frame rate and power saving by reducing the AD conversion period.

### SUMMARY OF THE INVENTION

In order to solve the aforementioned problem, the solid-state imaging device according to the present invention includes: a plurality of pixel circuits arranged in rows and columns, each of the pixel circuits outputting an analog signal corresponding to an amount of received light; a reference signal generating circuit which outputs a reference signal varying over time; and column AD conversion circuits each of which is provided for a corresponding one of the columns and converts the analog signal which is outputted from each of the pixel circuits arranged in the corresponding one of the columns to a digital signal based on a comparison between the analog signal and the reference signal. Each of the column AD conversion circuits includes: a comparator which compares the analog signal outputted from each of the pixel circuits with the reference signal; a counter which counts down and counts up predetermined clock pulses from an initial value until the comparator indicates a predetermined comparison result, the initial value being preset in the counter; and a latch which holds a value indicated by the counter. Each of the column AD conversion circuits (i) performs, after presetting a predetermined initial value to the counter, down-count processing in which each of the column AD conversion circuits counts down the clock pulses using the counter while comparing, in the comparator, a reset component that is an analog signal outputted from one of the pixel circuits which is yet to receive light with the reference signal, and holds in the latch a value indicated by the counter as a result of the down-count processing, and (ii) performs, after presetting the value held in the latch to the counter, up-count processing in which each of the column AD conversion circuits counts up the clock pulses using the counter while comparing, in the comparator, a signal component that is an analog signal outputted from one of the pixel circuits which has received light with the reference signal, and outputs a value indicated by the counter as a result of the up-count processing as the digital signal.

With such a configuration, a count value indicated by the counter as a result of the down-count processing can be latched, and the latched data can be used as the initial value in the up-count processing. The down-count processing is performed, for example, on the pixel circuits included in any one row selected from among rows that form one frame. Thus, the amount of down-count processing can be reduced compared to the conventional technique with which the down-count processing and the up-count processing are performed on all the pixel circuits to achieve the digital CDS.

With this, the amount of time and power consumed for the down-count processing can be reduced compared to the conventional technique. Consequently, it is possible to obtain the solid-state imaging device which can achieve high frame rate with low power consumption.

Furthermore, the column AD conversion circuit may perform the down-count processing on each of reset components outputted from n of the pixel circuits arranged in n rows, and hold in the latch an average value of values indicated by the counter as a result of the down-count processing performed for the n rows, n being an integer equal to or greater than two.

With such a configuration, the down-count processing is performed more than once. Thus, it is possible to improve accuracy of a down count value.

Furthermore, each of the column AD conversion circuits may perform the down-count processing in a vertical blanking period.

With such a configuration, after completing the down-count processing in the vertical blanking period, the signal component from each of the pixel circuits can be converted into a digital signal by performing only the up-count processing. With this, it is possible to eliminate inconsistency of operation, such as whether or not the down-count processing is performed for each of the pixel circuits, which can adversely affect quality of an output image. Furthermore, the down-count processing can be performed using the reset component outputted from the pixel circuit included in any row.

Furthermore, each of the pixel circuits may include: a photoelectric conversion element; a transfer switch element which transfers a charge from the photoelectric conversion element to a floating diffusion unit; an output element which outputs an analog signal corresponding to a voltage of the floating diffusion unit; and a reset switch element which connects the floating diffusion unit to a predetermined voltage, and each of the pixel circuits may output the analog signal as the reset component with (i) the transfer switch element in a non-conductive state and (ii) the reset switch element in a conductive state.

With such a configuration, it is possible to cause the pixel circuit included in any row to output the reset component for performing the down-count processing.

Furthermore, each of the column AD conversion circuits may perform the down-count processing on each of one or more reset components outputted from one or more of said pixel circuits arranged in an active pixel area for outputting the digital signal, and perform, after the down-count processing, only the up-count processing on the signal component outputted from each of the pixel circuits arranged in the active pixel area, and output a value indicated by the counter as a result of the up-count processing as the digital signal.

With such a configuration, after completing the down-count processing with one or more pixel circuits arranged within the active pixel area, the digital signal can be generated by performing only the up-count processing on each of the pixel circuits arranged within the active pixel area. With this, it is possible to eliminate inconsistency of operation, such as whether or not the down-count processing is performed for each of the pixel circuits, which can adversely affect quality of an output image.

Furthermore, each of the column AD conversion circuits may perform the down-count processing on each of reset components outputted from n of the pixel circuits arranged in n rows included in the active pixel area, and hold in the latch an average value of values indicated by the counter as a result of the down-count processing performed for the n rows, n being an integer equal to or greater than one.

With such a configuration, the down-count processing can be performed more than once. Thus, it is possible to improve accuracy of the down count value.

Furthermore, the present invention can be realized not only as the thus described solid-state imaging device but also as a method of driving the thus described solid-state imaging device.

The present invention makes it possible to latch the count value that is obtained by performing the down-count processing in advance, and use the latched data as the initial value in the up-count processing. The down-count processing is performed, for example, on the pixel circuits included in any one row selected from among rows that form one frame. Thus, the amount of down-count processing can be reduced compared to the conventional technique with which the down-count processing and the up-count processing are performed on all the pixel circuits to achieve the digital CDS.

With this, the amount of time and power consumed for the down-count processing can be reduced compared to the conventional technique. Consequently, it is possible to obtain the solid-state imaging device which can achieve high frame rate with low power consumption.

### BRIEF DESCRIPTION OF THE DRAWINGS

These and other objects, advantages and features of the invention will become apparent from the following description thereof taken in conjunction with the accompanying drawings that illustrate a specific embodiment of the present invention. In the Drawings:

FIG. 1 is a schematic diagram of a solid-state imaging device according to Embodiment 1 of the present invention;

FIG. 2 is a diagram showing operations in one frame performed by the solid-state imaging device according to Embodiment 1 of the present invention;

FIG. 3 is a timing diagram showing operations performed by the solid-state imaging device according to Embodiment 1 of the present invention to read a first row;

FIG. 4 is a timing diagram showing operations performed by the solid-state imaging device according to Embodiment 1 of the present invention to read a second row and the subsequent rows;

FIG. 5 is a diagram showing operations in one frame performed by a solid-state imaging device according to Embodiment 2 of the present invention;

FIG. 6 is a schematic diagram of a solid-state imaging device according to Embodiment 3 of the present invention;

FIG. 7A is a configuration diagram of a pixel circuit and FIG. 7B and FIG. 7C are driving timing diagrams of the pixel circuit according to Embodiment 3 of the present invention;

FIG. 8 is a diagram showing operations in one frame performed by the solid-state imaging device according to Embodiment 3 of the present invention;

FIG. 9 is a schematic diagram of a conventional solid-state imaging device;

FIG. 10 is a timing diagram showing operations performed by the conventional solid-state imaging device; and

FIG. 11 is a diagram showing operations in one frame performed by the conventional solid-state imaging device.

### DESCRIPTION OF THE PREFERRED EMBODIMENTS

The following describes preferred embodiments in detail with reference to drawings.

### Embodiment 1

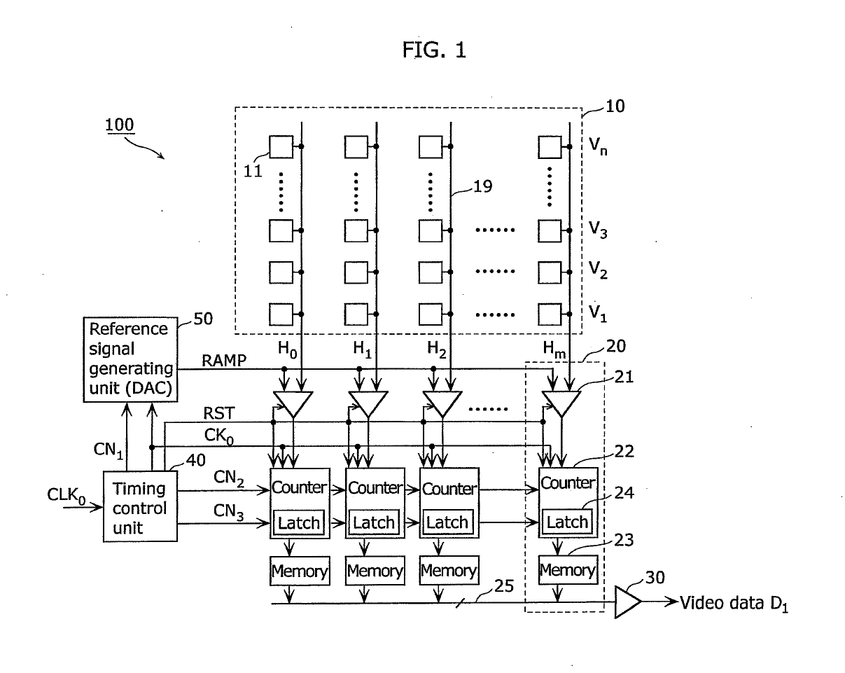

FIG. 1 is a schematic diagram of a solid-state imaging device 100 according to Embodiment 1 of the present invention.

As shown in FIG. 1, the solid-state imaging device 100 according to this embodiment includes: a pixel array (imaging region) 10 in which pixel circuits 11 are arranged in rows and columns; column AD conversion circuits 20 each of which is provided for a corresponding one of the columns of the pixel array 10 and converts a signal output from each of the pixel circuits 11 into a digital value; a reference signal generating unit 50 which generates using a DAC a reference signal RAMP which varies over time at a predetermined change rate; a timing control unit 40 which controls various timings; and an output circuit 30.

The timing control unit 40 generates various internal clocks based on a master clock CLK₀, and also generates an operation timing control signal for each of blocks. The signal outputted from the pixel circuit 11 is supplied to a corresponding one of the column AD conversion circuits 20 through a vertical signal line 19 (H₀, H₁ . . . , Hₘ).

The pixel circuit 11 includes at least a light sensitive element such as a photodiode or a photogate and is realized with a device structure which allows a signal generated by photoelectric conversion to be read out and a device structure which enables the pixel circuit 11 to perform initialization operation.

Each of the column AD conversion circuits 20 includes: a comparator 21, a counter 22, and a memory 23. The comparator 21 compares the reference signal RAMP obtained from the reference signal generating unit 50 with the pixel signal obtained from the pixel circuit 11 through the vertical signal line 19. The counter 22 includes a latch 24, and counts clock pulses inputted. The memory 23 holds a count value that is obtained by a counting performed by the counter 22 from when the reference signal generating unit 50 causes the reference signal to start to vary to when the comparator 21 indicates that the pixel signal matches the reference signal.

The pixel signal held in the memory 23 is outputted as video data D₁ to the outside via an output signal line 25 and the output circuit 30. Here, the comparator 21 includes an input capacitance for pixel noise cancelling, and performs a CDS by analog processing (hereinafter referred to as an “analog CDS”) according to a reset signal RST at the time when the pixel signal is read out.

The counter 22 has an up-down counter configuration, and performs a counting operation by switching between an up-count mode and a down-count mode according to a control signal CN₂ from the timing control unit 40.

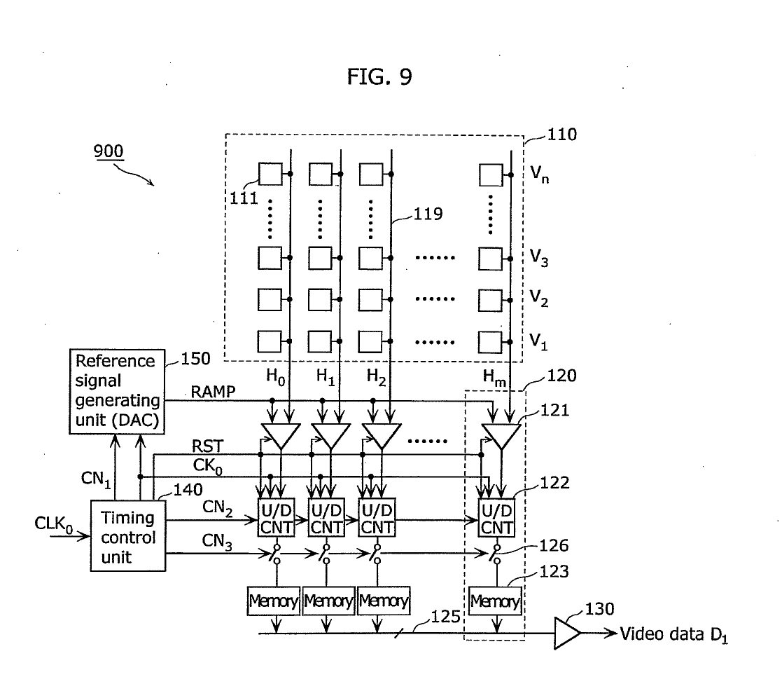

The solid-state imaging device 100 is the same as the conventional solid-state imaging device shown in FIG. 9 in that the column AD conversion circuit 20 includes the counter 22 but different in that the column AD conversion circuit 20 further includes the latch 24 that can hold the value of the counter 22 and that the value held in the latch 24 can be preset to the counter 22.

The following describes AD conversion operation performed by the solid-state imaging device 100.

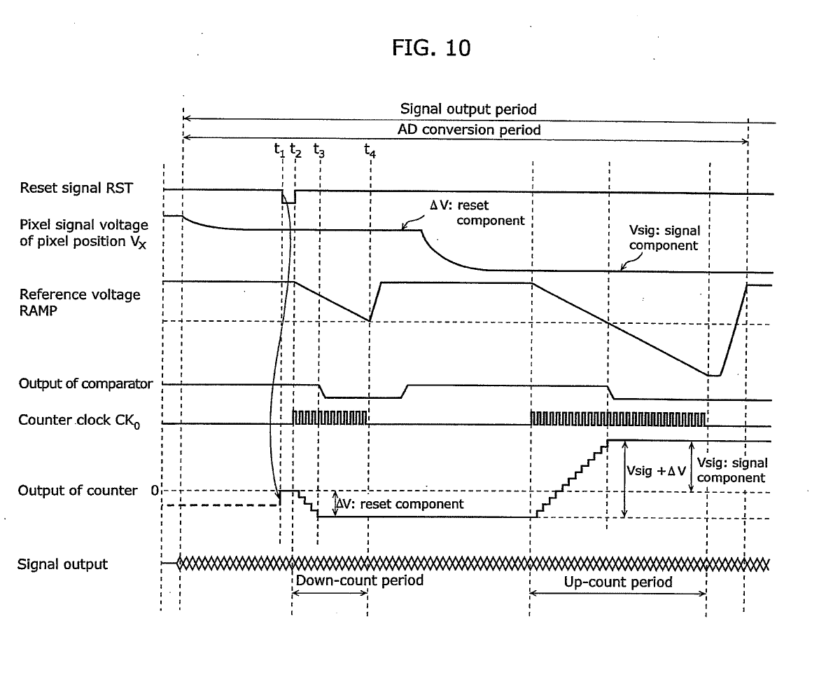

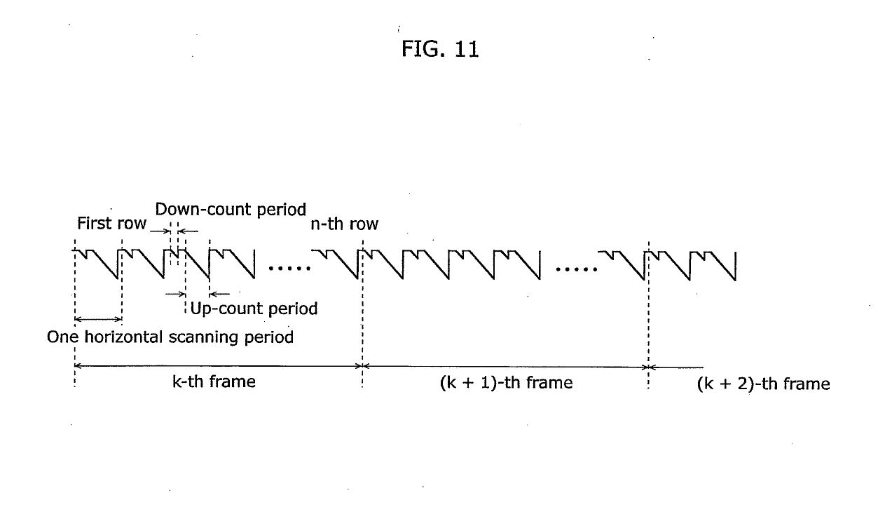

As shown in FIG. 10 and FIG. 11, to read out the pixels included in each of the rows, the conventional solid-state imaging device 900 performs the analog CDS and a digital CDS that is achieved by performing the down-count processing when reading a reset component ΔV and the up-count processing when reading a signal component V_{sig}.

When the digital CDS is performed to reduce variations such as a clock skew variation and a counter delay variation of each column that result in an error in the column AD conversion circuit 20, the down-count processing to achieve the digital CDS needs to be performed only for each of the columns and not for each of the pixels. Thus, it is not necessary to perform the down-count processing individually on the signal that is read out from the pixel circuit 11 in each row.

Thus, this embodiment is characterized in that (i) the operation of the down-count processing to achieve the digital CDS is performed only once per frame, and (ii) the AD conversion of the signal outputted from each of the pixel circuits 11 included in each row is performed by performing only the up-count operation using a down count value indicated by the counter as a result of the down-count processing, and thus the digital CDS is achieved.

With this, it is possible to shorten the AD conversion period at the time when the pixels in each row are read out. This makes it possible to achieve a high frame rate and, as a result of the reduced amount of the down-count processing, power saving.

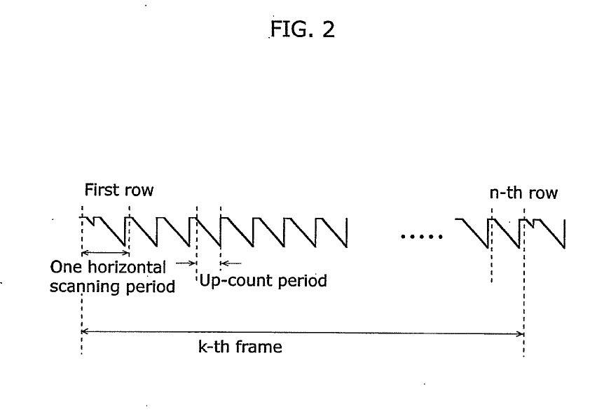

FIG. 2 shows operations performed by the solid-state imaging device 100 to read each row in a k-th frame.

According to FIG. 2, for a first row in the k-th frame, the solid-state imaging device 100 performs (i) the down-count processing on the reset component that is read out from the pixel circuit 11 to achieve the digital CDS and (ii) the up-count processing on the signal component that is read out from the pixel circuit 11, and thus achieves the digital CDS.

The down count value of the first row is held in the latch 24. For the second row and the subsequent rows up to an n-th row, the solid-state imaging device 100 performs the up-count processing using the count value held in the latch 24 as an initial value and thus achieves the digital CDS.

Thus, only the up-count processing is performed in the AD conversion period for the second row and the subsequent rows, making it possible to shorten the AD conversion period for reading one frame.

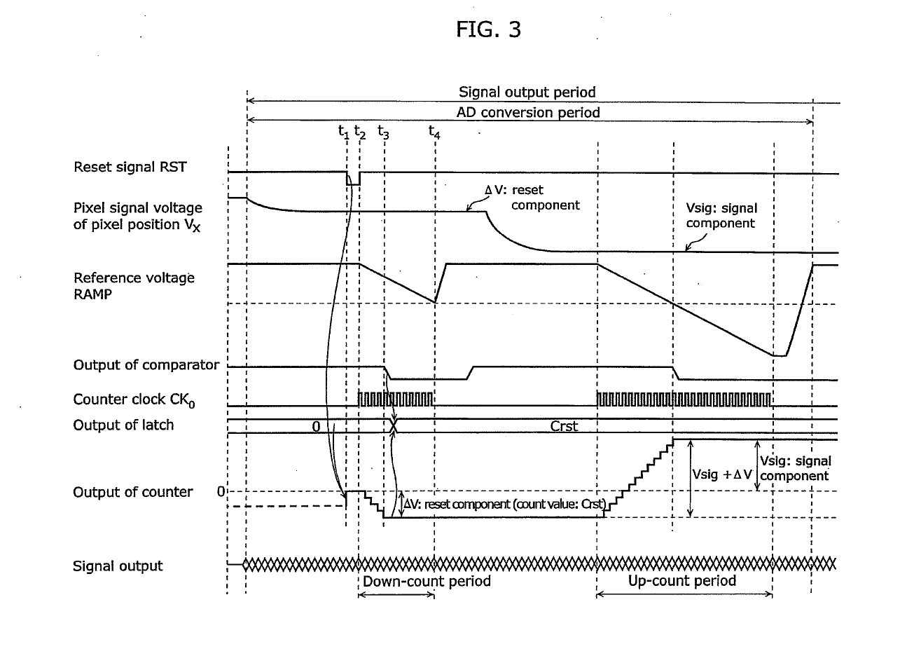

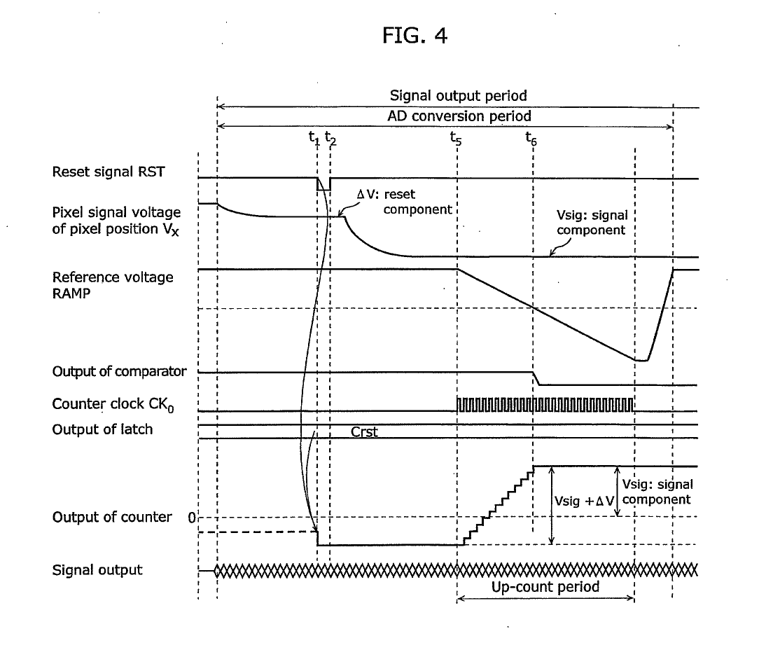

The following describes details of the AD conversion operation with reference to FIG. 3 and FIG. 4. FIG. 3 is a timing diagram showing operations performed by the solid-state imaging device 100 to read a first row. FIG. 4 is a timing diagram showing operations performed to read a second row and the subsequent rows. Note that the analog CDS is performed in the comparator 21 according to the reset signal RST shown in FIG. 3 and FIG. 4, which is the same as the operation performed by the above-described conventional solid-state imaging device.

Referring to FIG. 3, when an operation for the first row is started, the value held in the latch 24 is reset to a predetermined initial value (for example, 0) by initialization processing that is performed for each frame. The timing control unit 40 presets the count value of the counter 22 to the initial value 0, which is held in the latch 24, with the reset signal RST and sets the counter 22 to the down-count mode (time t₁). Furthermore, the timing control unit 40 causes each of the pixel circuits 11 in a first row V₁ to read out the pixel signal having the reset component ΔV. The pixel signal that is read out appears in the vertical signal line 19 (H₀, H₁ . . . , Hₘ). The timing control unit 40 resets the comparator 21, and provides a control signal CN₁ to the reference signal generating unit 50 when the pixel signal in the vertical signal line 19 becomes stable (time t₂).

In response, the reference signal generating unit 50 starts temporal variation of a reference signal RAMP. Simultaneously, the timing control unit 40 starts to provide a clock CK₀ to the counter 22 (time t₂). In response, the counter 22 starts to count down from the initial value 0.

The reference signal RAMP varies over time, and matches the reset component ΔV at a certain point of time (time t₃). Here, an output signal of the comparator 21 is inverted, and the counter 22 stops the count down accordingly. The count value Cᵣₛₜ at this time corresponds to the reset component ΔV, and the count value Cᵣₛₜ is held in the latch 24.

At the end of the down-count period (time t₄), the timing control unit 40 stops providing the control signal CN₁ to the reference signal generating unit 50, and simultaneously stops providing the clock CK₀ to the counter 22. Note that the providing of the clock CK₀ may alternatively stopped at times when the output signal of the comparator 21 is inverted. In this case, excess counting can be prevented, making it possible to further reduce power consumption.

Subsequently, the timing control unit 40 sets the counter 22 to the up-count mode, and causes each of the pixel circuits 11 in the first row V₁ to read out the pixel signal having the signal component V_{sig}. The timing control unit 40 sets the counter 22 to the up-count mode, and performs on the pixel signal that is read out the up-count operation from the value previously obtained by the count down.

As described above, the counter 22 is set to the down-count mode when the reset component ΔV is read out and to the up-count mode when the signal component V_{sig} is read out. With this, in effect, the subtraction is performed within the counter 22, making it possible to obtain a count value corresponding to the signal component V_{sig}.

The following describes the readout operation for the second row and the subsequent rows with reference to FIG. 4. When the operation for the second row and the subsequent rows are started, the latch 24 already has the down count value Cᵣₛₜ that is obtained by the counting performed for the readout of the first row.

As the readout operation of the second row and the subsequent rows, the timing control unit 40 causes each of the pixel circuits 11 in a row Vₓ (x=2, 3 . . . , n) that is a second row and the subsequent rows to read out a pixel signal having the reset component ΔV in the same manner as for the readout operation of the first row. The pixel signal that is read out appears in the vertical signal line 19 (H₀, H₁ . . . , Hₘ). The timing control unit 40 resets the comparator 21 with the reset signal RST, and presets the count value of the counter 22 to the value Cᵣₛₜ that is held in the latch 24 (time t₁).

When the pixel signal in the vertical signal line 19 is stabilized (time t₂), the timing control unit 40 sets the counter 22 to the up-count mode and causes each of the pixel circuits 11 in the second row and the subsequent rows to read out the pixel signal having the signal component V_{sig}.

The pixel signal that is read out appears in the vertical signal line 19 (H₀, H₁ . . . , Hₘ). When the pixel signal in the vertical signal line 19 is stabilized (time t₅), the timing control unit 40 provides the control signal CN₁ to the reference signal generating unit 50. In response, the reference signal generating unit 50 starts temporal variation of the reference signal RAMP.

Simultaneously, the timing control unit 40 starts to provide the clock CK₀ to the counter 22. In response, the counter 22 starts the up-count operation from the initial value Cᵣₛₜ.

The reference signal RAMP varies over time, and matches the signal component V_{sig} at a certain point of time (time t₆). Here, the output of the comparator 21 is inverted, and the counter 22 stops the count up accordingly.

As described, in the up-count operation, the counting is started from the initial value Cᵣₛₜ and thus the result of the count up corresponds to the signal component V_{sig}. Furthermore, with this, the digital CDS is also achieved on variations such as the clock skew variation and the counter delay variation in each column, which result in the error in the column AD conversion circuit 20.

As described above, in the readout operation of the first row, the down-count processing and the up-count processing are performed in the same manner as the conventional technique and thus the digital CDS is achieved to read out the signal component V_{sig} of the pixel. Here, the down count value Cᵣₛₜ is held in the latch 24. In the readout operation of the second row and the subsequent rows, the up-count processing is performed using as the initial value the down count value Cᵣₛₜ of the first row that is a latch data held in the latch 24, and thus the digital CDS is achieved to read out the signal component V_{sig} of the pixel.

Therefore, the solid-state imaging device 100 does not perform for the second row and the subsequent rows the down-count processing to achieve the digital CDS. Thus, the AD conversion period in one frame can be shorten, making it possible to further increase a frame rate and to reduce power consumed by the down-count processing.

Note that although this embodiment has described, as an example, the case where the predetermined initial value that is preset to the counter to perform operations for the first row is zero, the predetermined initial value is not limited to the above description. A down count width (bit number) may be taken into account in setting the predetermined initial value. (For example, when the bit number required for the count down is 6 bit, the initial value of the counter may be set to 2̂6=64.) Such configuration can be realized by resetting the value held in the latch 24 to 64 by the initialization processing that is performed for each frame. In this case, the down-count value obtained as a result of the readout of the first row does not be a negative value, making it possible to realize a counter with a simple configuration.

In addition, the down-count processing does not necessarily have to be performed in the readout operation of the first row, but may be performed in the readout operation of any selected row. Furthermore, it is preferable that the down-count processing be performed in a vertical blanking period. This is because, with the method in which the down-count processing is performed only on one row in the period when active pixels are read out, the readout operation is different between the row on which the down-count processing is performed and the other rows on which only the up-count processing is performed, and can possibly affect video data.

Furthermore, the number of the down-count processing is not limited to once for each frame. The same advantageous effect can be achieved by performing the down-count processing (i) once for more than one frame or (ii) once every time when modes are switched (for example, from a still picture mode to a moving picture mode, and the like).

Furthermore, although this embodiment has described the configuration in which the down-count processing is performed on the reset component of the pixel and the up-count processing is performed on the signal component, the configuration of the counter is not limited to the above. Alternately, with the counter, the up-count processing may be performed on the reset component of the pixel and the down-count processing may be performed on the signal component. In this case, the number of the up-count processing to achieve the digital CDS may be decreased. Furthermore, other various modifications can be made without departing from the gist of the present invention and are intended to be included within the scope of this invention.

### Embodiment 2

In Embodiment 1, down-count processing to achieve a digital CDS is performed only in a readout operation of a first row, and only up-count processing is performed in the readout operation of a second row and subsequent rows with a down count value Cᵣₛₜ as an initial value from which a count up is started, and thus the digital CDS is achieved. With this, an AD conversion period in the readout operation of one frame is shorten.

Embodiment 2 is characterized in performing the down-count processing in the readout operation of more than one row. Note that a configuration is made such that the down-count processing is performed at the time when a pixel in a peripheral pixel area other than an active pixel area is read out.

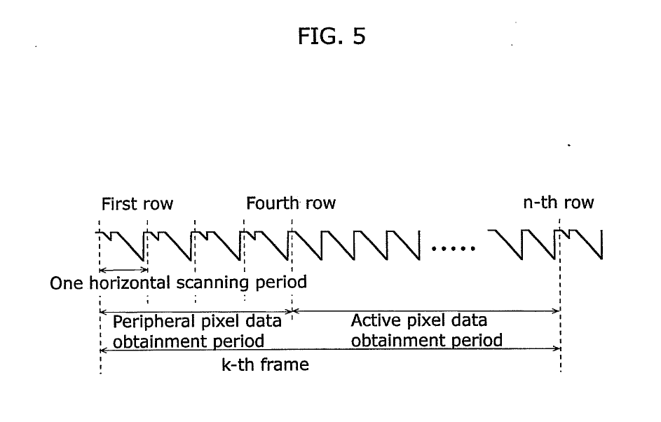

FIG. 5 shows operations performed in one frame by a solid-state imaging device 100 according to Embodiment 2.

FIG. 5 is a diagram showing readout operations in a k-th frame. This example is described on an assumption that a first row to a fourth row are the peripheral pixel area that is used solely for detecting a non-signal state level, and a fifth row and the subsequent rows are the active pixel area that is for outputting a digital signal as video data.

When the first row to the fourth row are read out, both the down-count processing and the up-count processing are performed as shown by a peripheral pixel data obtainment period in FIG. 5. At this time, an average value of the down count value of each of the rows is held in a latch 24.

Specifically, the down count average value is obtained by shifting, by two bits, integrated values of down count values for four rows. Performing the down-count processing more than once results in improved accuracy of the down count value to achieve the digital CDS.

When the fifth row and the subsequent rows are read out, as shown by an active pixel data obtainment period in FIG. 5, only the up-count processing is performed with a latch data held in the latch 24 as the initial value, and thus the digital CDS is achieved. With this, it is possible to shorten the AD conversion period, making it possible to achieve a high frame rate and power saving.

Although FIG. 5 illustrates the case where the down-count processing is performed for the first row to the fourth row, another configuration is also acceptable. The down-count processing may be performed for any selected n rows (n denotes an integer equal to or greater than two) and the average value of the down count value obtained from each of the n rows may be held in the latch 24. Furthermore, the n rows for which the down-count processing is performed need not be adjacent to one another but another configuration is possible to produce the same advantageous effects. The down-count processing may be performed for rows which are located apart from one another. Furthermore, the method for obtaining the average value of the down count values is not limited to the above. Any methods that can obtain the average value of the down count values for the n rows may be used, and various modifications can be made.

### Embodiment 3

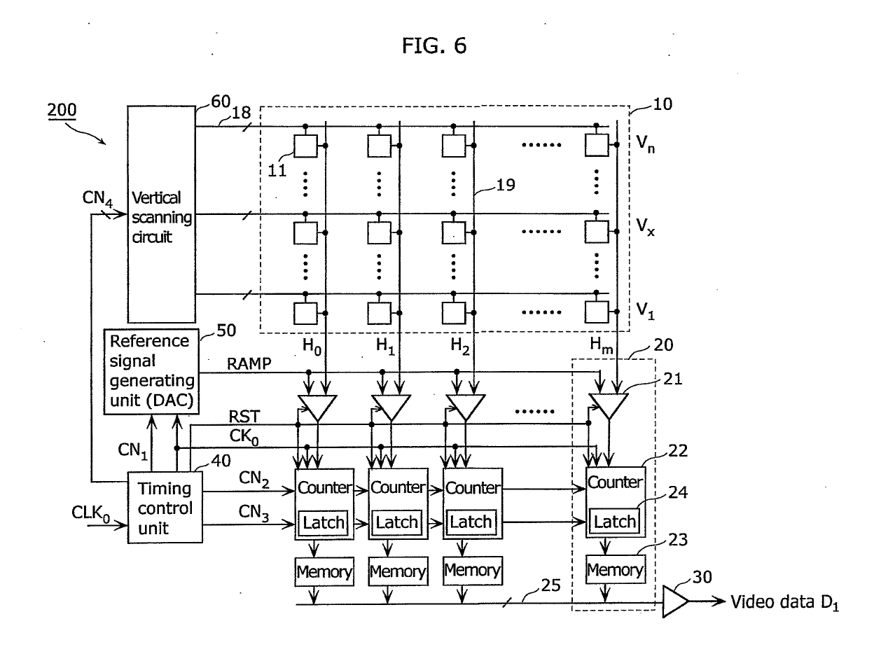

FIG. 6 is a schematic diagram of a solid-state imaging device 200 according to Embodiment 3 of the present invention. The following describes the difference between the solid-state imaging device 200 and the solid-state imaging device 100 according to Embodiment 1 and Embodiment 2.

Compared to the solid-state imaging device 100 shown in FIG. 1, the solid-state imaging device 200 is different in that a vertical scanning circuit 60 and a plurality of row control lines 18 are illustrated in FIG. 6 and a control signal CN₄, which indicates a period during which the down-count processing is to be performed, is supplied from a timing control unit 40 to a vertical scanning circuit 60. Each of the row control lines 18 includes a plurality of control lines.

Embodiment 2 described the configuration in which the down-count processing is performed at the time when the peripheral pixel is read out. However, the peripheral pixel area is usually located around the active pixel area. Thus, in the configuration in which the down-count processing is performed at the time when the peripheral pixel is read out, the row for which the down-count processing can be performed is limited to each of the rows on an upper side or a lower side of a physical area of the pixel array 10. In contrast, this embodiment is characterized in performing the down-count processing for a row located near the center of the pixel array 10 as well.

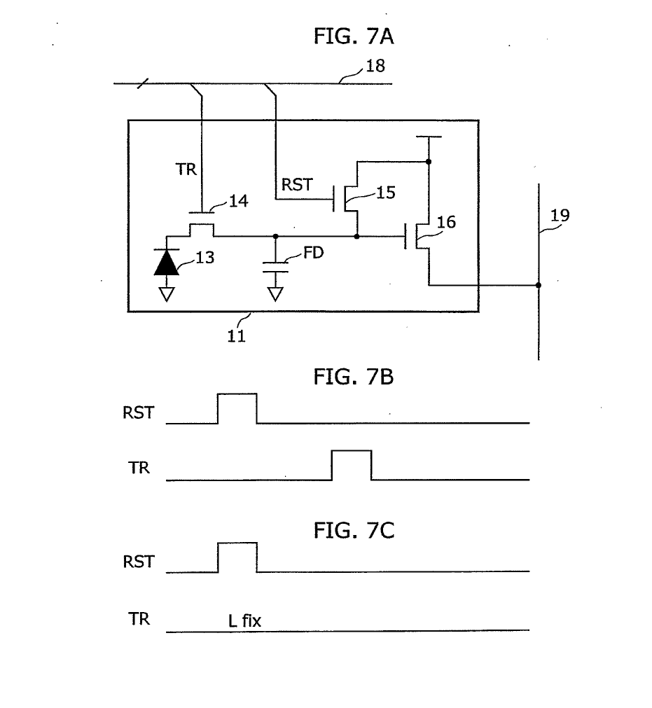

FIG. 7A is a circuit diagram showing an example of a configuration of a pixel circuit 11.

FIG. 7B and FIG. 7C are drive timing diagrams which show operations of the pixel circuit 11.

FIG. 7A shows that the pixel circuit 11 includes: a photoelectric conversion element 13; a transfer switch element 14 which transfers charge from the photoelectric conversion element 13 to a floating diffusion unit (hereinafter referred to as an “FD unit”); an output element 16 which outputs a potential of the FD unit; and a reset element 15 which resets the potential of the FD unit. When light is incident on the photoelectric conversion element 13, charge corresponding to the light is generated. The transfer switch element 14 transfers the charge generated in the photoelectric conversion element 13 to the FD unit according to a transfer control signal TR.

Furthermore, the output element 16 outputs the potential corresponding to the charge in the FD unit to a vertical signal line 19, and the reset element 15 resets the FD unit according to a reset control signal RST. Note that the transfer control signal TR and the reset signal RST are respectively provided, through separate control lines included in the row control line 18, to the pixel circuit 11 from the vertical scanning circuit 60. Furthermore, the vertical scanning circuit 60 is controlled according to the control signal CN₄ from the timing control unit 40.

Furthermore, FIG. 7B shows a general readout operation of a pixel. First, the reset signal RST causes the pixel circuit 11 to be reset, and then the transfer control signal TR causes the signal corresponding to the charge generated in the photoelectric conversion element 13 to be output.

However, when the down-count processing to achieve the digital CDS, which is a feature of the present invention, is to be performed not in the peripheral pixel area but in the active pixel area, the normal readout operation of the pixel does not have to be performed.

In this case, as shown in FIG. 7C, the transfer control signal TR is not operated and the charge transfer from the photoelectric conversion element 13 to the FD unit is not performed. In this state, driving in which the pixel circuit 11 is reset with the reset signal RST is performed (hereinafter referred to as “dummy drive”). The dummy drive is performed according to the control signal CN₄ from the timing control unit 40 on each of the pixel circuits 11 in any row Vₓ that is selected by the vertical scanning circuit 60.

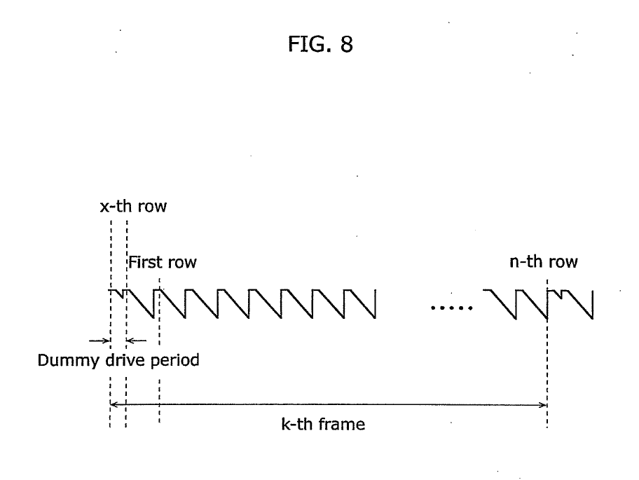

Next, FIG. 8 shows operations performed in one frame by the solid-state imaging device 200 according to this embodiment.

As shown in FIG. 8, when the readout operation of a k-th frame is started, the vertical scanning circuit 60 performs the dummy drive, which involves only the down-count processing, according to the control signal CN₄ from the timing control unit 40 on the selected row Vₓ located near the center of the pixel array 10. The down count value is held in the latch 24. Then, in a sequential readout operation from the first row, only the up-count processing is performed with the latch data held in the latch 24 as the initial value from which the counting is started, and the digital CDS is thus achieved.

Note that the row Vₓ for which the down-count processing to achieve the digital CDS is performed does not necessarily have to be selected from among the rows located near the center of the pixel array 10. When the down-count processing is to be performed for any selected row in the pixel array 10 regardless of the peripheral pixel area and the active pixel area, the down-count processing can be performed by performing the dummy drive on each of the pixel circuits 11 in any row of the pixel array 10.

When the driving is performed as described above, after performing the down-count processing, readout operation of each row only requires the up-count processing. Thus, it is possible to shorten the AD conversion period, making it possible to achieve a high frame rate and achieve power saving.

It is to be noted that, although this embodiment has described an example where the down-count processing is performed for one row that is located near the center of the active pixel area, the down-count processing may be performed on any selected n rows (n denotes an integer equal to or greater than two) in the active pixel area. In this case, an average of the down count values for the n rows is held in the latch 24.

When the down-count processing is performed, for example, for n rows located near the center, near the upper side, and near the lower side of the active pixel area, it is possible to obtain the down count value which takes into account an inter pixel dependency of the pixel array 10. This makes it possible to achieve the digital CDS in higher precision. Other various modifications can be made without departing from the gist of the present invention and are intended to be included within the scope of this invention.

(Comparison with a Conventional Technique)

The following describes the effectiveness of a solid-state imaging device and a driving method of the solid-state imaging device according to the embodiments of the present invention based on a comparison with the driving method according to a conventional technique.

FIG. 11 is a diagram showing operations in one frame performed by the solid-state imaging device according to the conventional technique.

As described in the section of Description of the Related Art, to read a first row to an n-th row in a k-th frame, the conventional technique requires a down-count period for reading a reset component of a pixel and an up-count period for reading a signal component of the pixel to read out pixel data from each of the rows.

As described, in the conventional driving method, a readout period of the pixel data of each of the rows, i.e. an AD conversion period, includes the down-count period and the up-count period. Thus, to output video data for one frame, the down down-count period and the up-count period are necessary for each of the rows.

Therefore, when the conventional operation shown in FIG. 11 is performed, a frame rate is constrained by the down-count period and the up-count period that are included in the AD conversion period of all the rows that form one frame.

Furthermore, as the number of bits of the AD conversion gets larger, the number of bits necessary for the count down needs to be set larger. Since the down-count period gets longer according to the number of bits, achieving a high frame rate becomes even more difficult.

In contrast, according to the solid-state imaging device and the driving method of the solid-state imaging device according to the present invention, although it is similar to the conventional technique in the sense that the up-count period is necessary for all the rows, it is sufficient when a part of the rows (for example, only one row) that form one frame has the down-count period.

Thus, the AD conversion period required for one frame is shorten, which makes it possible to realize the solid-state imaging device and the driving method of the solid-state imaging device which can achieve a high frame rate and power saving.

### INDUSTRIAL APPLICABILITY

A solid-state imaging device and a driving method of the solid-state imaging device according to the present invention are applicable to various still cameras and video cameras. The solid-state imaging device and a driving method of the solid-state imaging device according to the present invention can achieve a high frame rate with low power consumption, and are thus particularly suitable for applications to mobile data terminals, portable small cameras, and the like.

What is claimed is:

1. A solid-state imaging device comprising:
a plurality of pixel circuits arranged in rows and columns, each of said pixel circuits outputting an analog signal corresponding to an amount of received light;
a reference signal generating circuit which outputs a reference signal varying over time; and
column AD conversion circuits each of which is provided for a corresponding one of the columns and converts the analog signal which is outputted from each of said pixel circuits arranged in the corresponding one of the columns to a digital signal based on a comparison between the analog signal and the reference signal,
wherein each of said column AD conversion circuits includes:
a comparator which compares the analog signal outputted from each of said pixel circuits with the reference signal;
a counter which counts down and counts up predetermined clock pulses from an initial value until said comparator indicates a predetermined comparison result, the initial value being preset in said counter; and
a latch which holds a value indicated by said counter, and
each of said column AD conversion circuits:
performs, after presetting a predetermined initial value to said counter, down-count processing in which each of said column AD conversion circuits counts down the clock pulses using said counter while comparing, in said comparator, a reset component that is an analog signal outputted from one of said pixel circuits which is yet to receive light with the reference signal, and holds in said latch a value indicated by said counter as a result of the down-count processing; and
performs, after presetting the value held in said latch to said counter, up-count processing in which each of said column AD conversion circuits counts up the clock pulses using said counter while comparing, in said comparator, a signal component that is an analog signal outputted from one of said pixel circuits which has received light with the reference signal, and outputs a value indicated by said counter as a result of the up-count processing as the digital signal.

2. The solid-state imaging device according to claim 1,
wherein each of said column AD conversion circuits
performs the down-count processing on each of reset components outputted from n of said pixel circuits arranged in n rows, and holds in said latch an average value of values indicated by said counter as a result of the down-count processing performed for the n rows, n being an integer equal to or greater than two.

3. The solid-state imaging device according to claim 1,
wherein each of said column AD conversion circuits performs the down-count processing in a vertical blanking period.

4. The solid-state imaging device according to claim 1,
wherein each of said pixel circuits includes: a photoelectric conversion element; a transfer switch element which transfers a charge from said photoelectric conversion element to a floating diffusion unit; an output element which outputs an analog signal corresponding to a voltage of the floating diffusion unit; and a reset switch element which connects the floating diffusion unit to a predetermined voltage, and
each of said pixel circuits outputs the analog signal as the reset component with (i) said transfer switch element in a non-conductive state and (ii) said reset switch element in a conductive state.

5. The solid-state imaging device according to claim 4,
wherein each of said column AD conversion circuits performs the down-count processing on each of one or more reset components outputted from one or more of said pixel circuits arranged in an active pixel area for outputting the digital signal, and
performs, after the down-count processing, only the up-count processing on the signal component outputted from each of said pixel circuits arranged in the active pixel area, and outputs a value indicated by said counter as a result of the up-count processing as the digital signal.

6. The solid-state imaging device according to claim 5,
wherein each of said column AD conversion circuits performs the down-count processing on each of reset components outputted from n of said pixel circuits arranged in n rows included in the active pixel area, and holds in said latch an average value of values indicated by said counter as a result of the down-count processing performed for the n rows, n being an integer equal to or greater than one.

7. A method of driving a solid-state imaging device which includes: a plurality of pixel circuits arranged in rows and columns, each of the pixel circuits outputting an analog signal corresponding to an amount of received light; a reference signal generating circuit which outputs a reference signal varying over time; and column AD conversion circuits each of which is provided for a corresponding one of the columns and includes a comparator, a counter, and a latch, and converts the analog signal which is outputted from each of the pixel circuits arranged in the corresponding one of the columns to a digital signal based on a comparison between the analog signal and the reference signal, said method of driving comprising:
presetting a predetermined initial value to the counter;
counting down, after said presetting of the initial value, a predetermined clock pulses from the initial value until the comparator indicates a predetermined comparison result using the counter while comparing, in the comparator, a reset component that is an analog signal outputted from one of the pixel circuits which is yet to receive light with the reference signal;
holding in the latch a value indicated by the counter as a result of said counting down;
presetting the value held in the latch to the counter;
counting up, after said presetting of the value held in the latch, the clock pulses using the counter while comparing, in the comparator, a signal component that is an analog signal outputted from one of the pixel circuits which has received light with the reference signal; and
outputting a value indicated by the counter as a result of said counting up as the digital signal.
